(19) United States
(12) Patent Application Publication
(10) Pub. No.: US 2007/0105348 A1
(43) Pub. Date: May 10, 2007

(54) Wafer processing method

(75) Inventor: Kazuma Sekiya, Tokyo (JP)

Correspondence Address: SMITH, GAMBRELL & RUSSELL, 1850 M STREET, N.W., SUITE 800, WASHINGTON, DC, 20036, US

(73) Assignee: Disco Corporation

(21) Appl. No.: 11/586,632

(22) Filed: Oct. 26, 2006

(30) Foreign Application Priority Data
Nov. 8, 2005 (JP) 2005-323533

(51) Int. Cl. H01L 21/00

(52) U.S. Cl. 438/464

(57) ABSTRACT

A wafer processing method for dividing a wafer having devices which are formed in areas sectioned by a plurality of streets formed in a lattice pattern on the front surface, along the streets, comprising a protective tape affixing step for putting a protective tape whose adhesive force is reduced by an external stimulus, on the front surface of the wafer; a rear surface grinding step for grinding the rear surface of the wafer having the protective tape to a predetermined thickness; a wafer supporting step for supporting the rear surface of the wafer subjected to the rear surface grinding step by a wafer supporting means; a dividing step for dividing the wafer supported by the wafer supporting means into individual chips along the streets together with the protective tape; and an adhesive force reducing step for reducing the adhesive force of the protective tape by providing an external stimulus to the protective tape in a state where the wafer divided into individual chips by the dividing step is supported by the wafer supporting means.

### FIELD OF THE INVENTION

The present invention relates to a wafer processing method for dividing a wafer having devices which are formed in areas sectioned by a plurality of streets formed in a lattice pattern on the front surface, along the plurality of streets.

### DESCRIPTION OF THE PRIOR ART

In the manufacturing process of a semiconductor device, for example, individual chips are manufactured by forming a device such as IC, LSI or CCD in a plurality of areas sectioned by cutting lines called “streets” formed in a lattice pattern on the front surface of a substantially disk-like wafer and dividing the wafer into respective areas in which the device is each formed, along the streets. A cutting machine called dicing machine generally is used as the dividing machine for dividing the wafer to cut the wafer along the streets with a cutting blade having a thickness of about 40 μm. The thus obtained chips are packaged and widely used in electric appliances such as portable telephones and personal computers.

To divide the wafer along the streets, the rear surface of the wafer is ground beforehand to obtain a predetermined thickness. When the rear surface of the wafer is to be ground, a protective tape is put on the front surface of the wafer to protect the devices formed on the front surface of the wafer. This protective tape is removed after the rear surface of the wafer is ground. To facilitate this removal, JP-A 11-238710 discloses a method in which a thermally shrinkable adhesive tape is put on the front surface of a wafer and after the rear surface of the wafer is ground, the adhesive tape is removed by heating it.

Further, when the wafer is to be cut along the streets, to facilitate the handling such as conveyance of the wafer, the wafer is held on the chuck table of a cutting machine in a state where its rear surface is put on the surface of a dicing tape mounted on an annular frame, and cut along the streets of the wafer held on the chuck table.

To cut the wafer along the streets, the cutting is carried out while cutting water is supplied. At this point, dirty water containing grinding chips produced by cutting adheres to the front surface of a device, thereby reducing the quality of the device. Particularly when the device is an image pick-up device such as CCD, the reduction of its quality is marked. This problem also arises when a laser beam is applied along the streets formed on the wafer to divide the wafer along the streets. That is, when the laser beam is applied to the wafer, debris are produced and adhere to the front surface of a device, thereby reducing the quality of the device.

Although the adhesion of grinding chips or debris to the front surface of the device can be prevented by putting a protective member on the front surface of the wafer at the time when the wafer is to be cut along the streets, the step of putting the protective member on the wafer must be carried out. Therefore, this has a problem with productivity.

### SUMMARY OF THE INVENTION

It is an object of the present invention to provide a wafer processing method capable of grinding the rear surface of a wafer and dividing it along streets without reducing productivity and further preventing grinding chips or debris from adhering to the front surface of the wafer.

To attain the above object, according to the present invention, there is provided a wafer processing method for dividing a wafer having a plurality of streets formed in a lattice pattern on the front surface and having devices formed in a plurality of areas sectioned by the plurality of streets, along the streets, comprising:

a protective tape affixing step for putting a protective tape whose adhesive force is reduced by an external stimulus, on the front surface of the wafer;

a rear surface grinding step for grinding the rear surface of the wafer having the protective tape to a predetermined thickness;

a wafer supporting step for supporting the ground rear surface of the wafer by wafer supporting means;

a dividing step for dividing the wafer supported by the wafer supporting means into individual chips along the streets together with the protective tape; and

an adhesive force reducing step for reducing the adhesive force of the protective tape by providing an external stimulus to the protective tape in a state where the wafer divided into individual chips by the dividing step is supported by the wafer supporting means.

The above protective tape is thermally shrinkable under heating, and is heated in the above adhesive force reducing step.

The above wafer supporting means is composed of an annular frame and a dicing tape which is so mounted as to cover the opening of the annular frame and has an adhesive layer on the surface, and the above wafer supporting step is to put the rear surface of the wafer on the surface of the dicing tape.

According to the present invention, a protective tape whose adhesive force is reduced by an external stimulus is used as the protective tape which is put on the front surface of the wafer to protect the front surface of the wafer before the step of grinding the rear surface of the wafer, and the step of dividing the wafer along the streets formed in a lattice pattern in a state that the protective tape has been affixed to the front surface of the wafer, after the rear surface grinding step. Therefore, a protective tape does not need to be put on the front surface of the wafer 2 again in order to prevent grinding chips produced by cutting from adhering to the front surfaces of devices in the dividing step and consequently, the productivity is not reduced.

Since a protective tape whose adhesive force is reduced by an external stimulus is used as the protective tape which is put on the front surface of the wafer, protective tape pieces produced for respective chips can be easily removed by applying an external stimulus such as heating to the protective tape after the above dividing step to reduce its adhesive force. Therefore, it does not affect the subsequent die bonding step.

### BRIEF DESCRIPTION OF THE DRAWINGS

FIG. 1 is a perspective view of a wafer to be divided by the wafer processing method of the present invention;

FIGS. 2(a) and 2(b) are diagrams explaining the protective tape affixing step in the wafer processing method of the present invention;

FIG. 3 is a diagram explaining the rear surface grinding step in the wafer processing method of the present invention;

FIG. 4 is a perspective view showing a state of the wafer put on the surface of a dicing tape mounted on an annular frame by carrying out the wafer supporting step in the wafer processing method of the present invention;

FIG. 5 is a perspective view of a principal section of a cutting machine for carrying out the dividing step in the wafer processing method of the present invention;

FIGS. 6(a) and 6(b) are diagrams explaining the dividing step in the wafer processing method of the present invention;

FIG. 7 is a partially enlarged sectional view of the wafer subjected to the dividing step shown in FIGS. 6(a) and 6(b);

FIG. 8 is a diagram explaining the adhesive force reducing step in the wafer processing method of the present invention; and

FIG. 9 is an explanatory diagram showing a state that protective tape pieces affixed to the front surfaces of chips are curved by carrying out the adhesive force reducing step shown in FIG. 8.

### DETAILED DESCRIPTION OF THE PREFERRED EMBODIMENTS

Preferred embodiments of the present invention will be described in detail hereinunder with reference to the accompanying drawings.

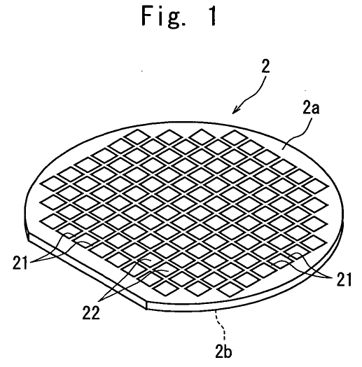

FIG. 1 is a perspective view of a wafer to be divided into individual chips according to the present invention. The wafer 2 shown in FIG. 1 has a plurality of streets 21 formed in a lattice pattern on the front surface 2a of a substrate having a thickness of, for example, 700 μm. On the front surface 2a of the wafer 2, devices 22 such as CCD's are formed in a plurality of areas sectioned by the plurality of streets 21. A wafer processing method for dividing this wafer 2 into individual chips will be described hereinbelow.

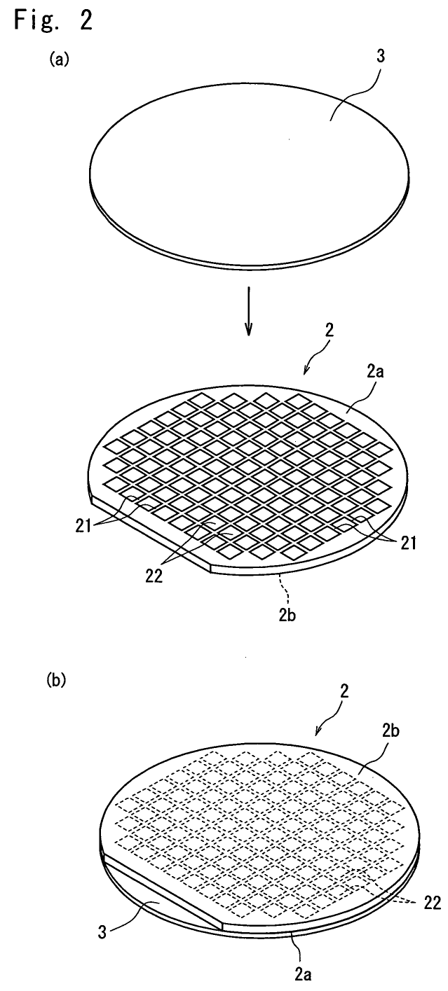

A protective tape affixing step of putting a protective tape 3 whose adhesive force is reduced by an external stimulus, on the front surface 2a of the above-described wafer 2 is first carried out, as shown in FIGS. 2(a) and 2(b). A thermally shrinkable adhesive tape which is shrunk by heating is used as the protective tape 3 in the illustrated embodiment. An adhesive tape disclosed, for example, by JP-A 11-238710 can be used as this thermally shrinkable adhesive tape. A tape having an adhesive layer which is cured upon exposure to ultraviolet radiation may also be used as the protective tape 3 whose adhesive force is reduced by an external stimulus.

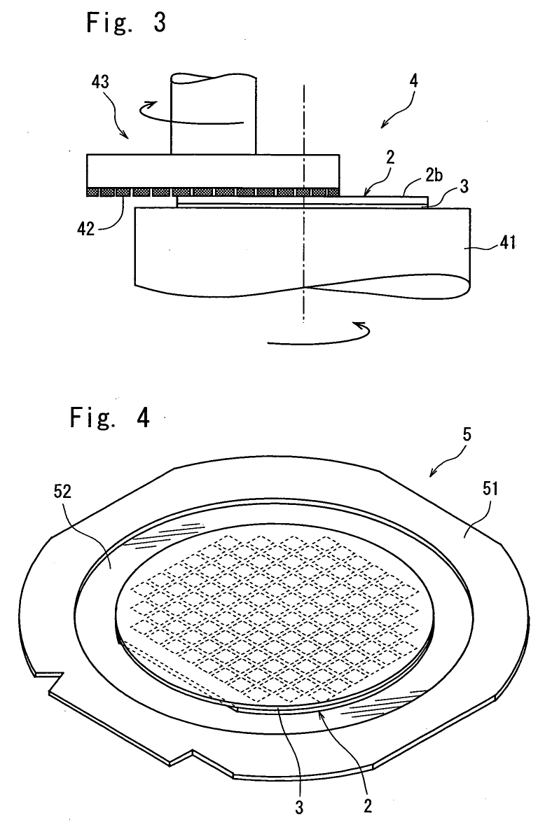

After the protective tape 3 is put on the front surface 2a of the wafer 2 by carrying out the above protective tape affixing step, next comes a rear surface grinding step of grinding the rear surface 2b of the wafer 2 to form a predetermined thickness. This rear surface grinding step is carried out by using a grinding machine 4 shown in FIG. 3. That is, the grinding machine 4 shown in FIG. 3 comprises a chuck table 41 for holding a workpiece and a grinding tool 43 having a grinding stone 42 for grinding the workpiece held on the chuck table 41. In the rear surface grinding step, the protective tape 3 side of the wafer 2 is placed on the chuck table 41 of the grinding machine 4 (therefore, the rear surface 2b of the wafer 2 faces up), and the wafer 2 is suction-held on the chuck table 41 by activating a suction means that is not shown. The grinding tool 43 is rotated at 6,000 rpm, for example, while the chuck table 41 is rotated at 300 rpm, for example, brought into contact with the rear surface 2b of the wafer 2 and further moved (grinding-fed) downward a predetermined distance to grind the rear surface 2b of the wafer 2 to form a predetermined thickness (for example, 300 μm).

Next comes a wafer supporting step of supporting the rear surface 2b of the wafer 2 which has been subjected to the above rear surface grinding step by a wafer supporting means. In the embodiment shown in FIG. 4, the wafer supporting means 5 is composed of an annular frame 51 and a dicing tape 52 whose outer peripheral portion is mounted on the annular frame 51 in such a manner as to cover the inner opening of the annular frame 51. The above dicing tape 52 has an about 5 μm-thick acrylic resin-based adhesive layer on the surface of a 70 μm-thick sheet substrate made of polyvinyl chloride (PVC) in the illustrated embodiment. The rear surface 2b of the wafer 2 is put on the surface of the dicing tape 52 of the thus constituted wafer supporting means 5. Therefore, the protective tape 3 on the front surface 2a of the wafer 2 faces up.

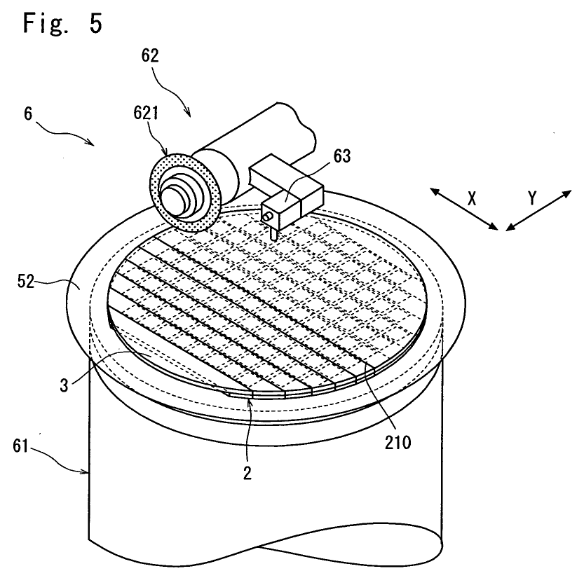

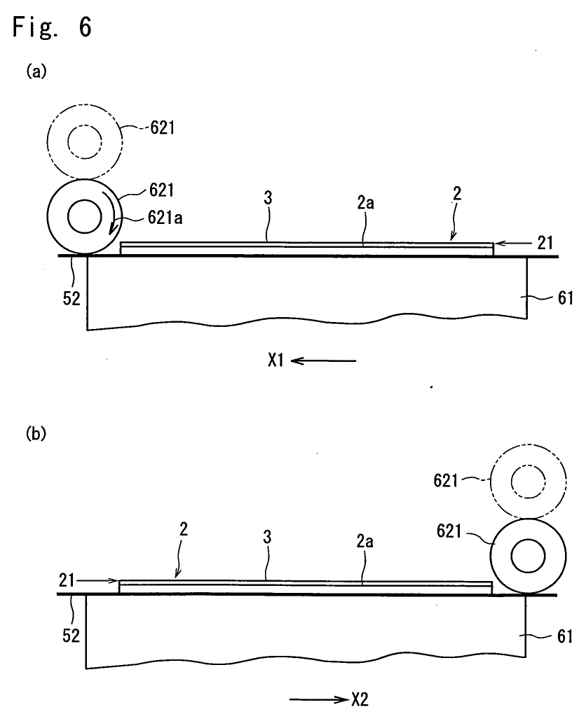

After the above wafer supporting step, next comes a dividing step of dividing the wafer 2 whose rear surface 2b is put on the surface of the dicing tape 52 mounted on the annular frame 51, along the streets 21 into individual chips together with the protective tape 3. This dividing step is carried out by using a cutting machine 6 shown in FIG. 5 that is generally used as a dicing machine. That is, the cutting machine 6 comprises a chuck table 61 having a suction-holding means, a cutting means 62 having a cutting blade 621 and an image pick-up means 63 for picking up an image of the workpiece held on the chuck table 61. The chuck table 61 is designed to be moved in a cutting-feed direction indicated by an arrow X in FIG. 6 by a cutting-feed mechanism. The chuck table 61 is also designed to be rotated by a rotating mechanism that is not shown. Further, the cutting means 62 is designed to be moved in an indexing-feed direction indicated by an arrow Y by an indexing-feed mechanism that is not shown. The above image pick-up means 63 is arranged on the same line as the cutting blade 621 in the cutting-feed direction indicated by the arrow X. This image pick-up means 63 comprises an infrared illuminating means for applying infrared radiation to the workpiece, an optical system for capturing the infrared radiation applied by the infrared illuminating means and an image pick-up device (infrared CCD) for outputting an electric signal corresponding to the infrared radiation captured by the optical system in addition to an ordinary image pick-up device for picking up an image with visible radiation in the illustrated embodiment. An image signal is supplied to a control means that is not shown.

The dividing step which is carried out with the above cutting machine 6 will be described hereinunder with reference to FIG. 5 to FIG. 7.

That is, as shown in FIG. 5, the dicing tape 52 affixed to the wafer 2 in the above wafer supporting step is placed on the chuck table 61 of the cutting machine 6. By activating the suction means that is not shown, the wafer 2 is held on the chuck table 61 via the dicing tape 52. In FIG. 5 which does not show the annular frame 51 on which the dicing tape 52 is mounted, the annular frame 51 is held by a suitable frame holding means provided on the chuck table 61. Thus, the chuck table 61 suction-holding the wafer 2 is positioned right below the image pick-up means 63 by the cutting-feed mechanism that is not shown.

After the chuck table 61 is positioned right below the image pick-up means 63, the alignment step for detecting the area to be cut of the semiconductor wafer 2 is carried out by using the image pick-up means 63 and the control means that is not shown. That is, the image pick-up means 63 and the control means (not shown) carry out image processing such as pattern matching, etc. to align a street 21 formed in a predetermined direction of the wafer 2 with the cutting blade 621, thereby performing the alignment of the area to be cut. Further, the alignment of the area to be cut is also carried out on streets 21 that is formed on the wafer 2 and extends in a direction perpendicular to the above predetermined direction. Although the protective tape 3 is affixed to the front surface 2a of the wafer 2 at this point, as the image pick-up means 63 is constituted by the infrared illuminating means, the optical system for capturing infrared radiation and the image pick-up device (infrared CCD) for outputting an electric signal corresponding to the infrared radiation as described above, an image of the street 21 can be picked up through the protective tape 3.

After the street 21 formed on the wafer 2 held on the chuck table 61 is detected and the alignment of the area to be cut is carried out as described above, the chuck table 61 holding the wafer 2 is moved to a cutting start position of the area to be cut. At this point, as shown in FIG. 6(a), the wafer 2 is positioned such that one end (left end in FIG. 6(a)) of the street 21 to be cut is located on the right side by a predetermined distance of a position right below the cutting blade 621.

After the chuck table 61, that is, the wafer 2 is moved to the cutting start position of the area to be cut, the cutting blade 621 is moved down from a standby position shown by a two-dot chain line in FIG. 6(a) to a predetermined cutting-feed position shown by a solid line. This cutting-feed position is set to a position where the lower end of the cutting blade 621 reaches the dicing tape 52 affixed to the rear surface 2b of the wafer 2.

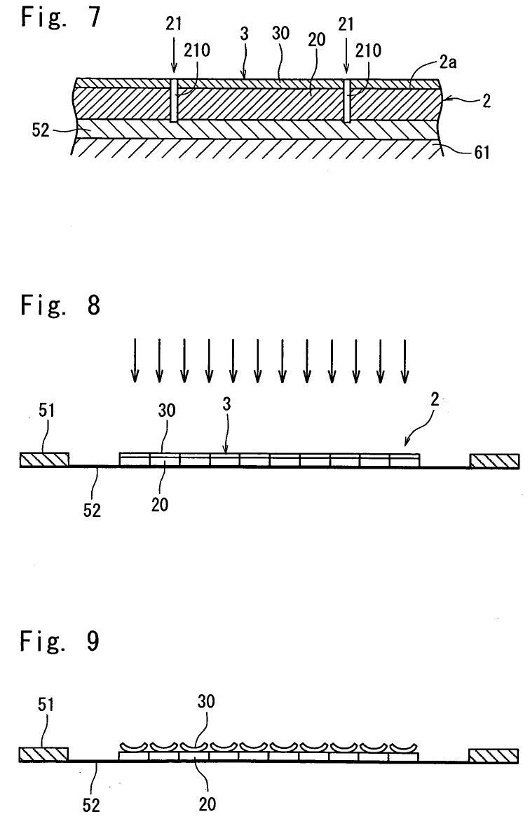

Thereafter, the cutting blade 621 is rotated at a predetermined revolution in a direction indicated by an arrow 621a in FIG. 6(a), and the chuck table 61, that is, the wafer 2 is moved at a predetermined cutting-feed rate in a direction indicated by an arrow X1 in FIG. 6(a). When the chuck table 61, that is, the wafer 2 reaches a position where the other end (right end in FIG. 6(b)) of the street 21 is located on the left side by a predetermined distance of a position right below the cutting blade 621, as shown in FIG. 6(b), the movement of the chuck table 61, that is, the wafer 2 is stopped. A groove 210 is formed along the street 21 in the wafer 2 by thus moving the chuck table 61, that is, the wafer 2 in the cutting-feed direction as shown in FIG. 7, whereby the wafer and the protective tape 3 affixed to the front surface 2a are divided (dividing step).

Subsequently, the cutting blade 621 is moved up to the standby position shown by the two-dot chain line in FIG. 6(b), and the chuck table 61, that is, the wafer 2 is moved in a direction indicated by an arrow X2 in FIG. 6(b) to return to the position shown in FIG. 6(a). The chuck table 61, that is, the wafer 2 is then moved a distance corresponding to the interval between the streets 21 in a direction (indexing-feed direction) perpendicular to the sheet so as to locate a street 21 to be cut next at a position corresponding to the cutting blade 621. After the street 21 to be cut next is located at a position corresponding to the cutting blade 621 as described above, the above-mentioned dividing step is carried out.

The above dividing step is carried out under the following processing conditions, for example.
Cutting blade: outer diameter of 52 mm, thickness of 40 μm
Revolution of cutting blade: 40,000 rpm
Cutting-feed rate: 50 mm/sec.

The above dividing step is carried out along all the streets 21 formed on the wafer 2. As a result, the wafer 2 is divided into individual chips (devices) 20 along the streets 21, and the protective tape 3 is also cut along the streets 21 to be divided into individual protective tape pieces 30. In the above dividing step, grinding chips are produced by cutting with the cutting blade 621. The grinding chips are mixed with cutting water supplied to a cutting portion to produce dirty water which runs over the wafer 2. Since the protective tape 3 is affixed to the front surface 2a of the wafer 2 in the illustrated embodiment, however, the grinding chips do not adhere to the devices 22 formed on the front surface 2a of the wafer 2.

Next comes an adhesive force reducing step of reducing the adhesive force of the protective tape 3 by giving an external stimulus to the protective tape 3 in a state where the wafer 2 divided into individual chips by the dividing step is put on the surface of the dicing tape 52 mounted on the annular frame 51. Since a thermally shrinkable adhesive tape is used as the protective tape 3 in the illustrated embodiment, the protective tape 3 is heated in a state where the wafer 2 divided into individual chips 20 is affixed to the surface of the dicing tape 52 mounted on the annular frame 51 as shown in FIG. 8. To heat the protective tape 3, hot water heated at 50 to 80° C. may be poured on the protective tape 3, or hot air may be blown against the protective tape 3. As a result, the protective tape pieces 30 affixed to the front surfaces of the chips 20 are shrunk by heating and curved as shown in FIG. 9. Accordingly, the protective tape pieces 30 affixed to the front surfaces of the chips 20 can be easily removed due to their reduced adhesive force.

In the illustrated embodiment, as described above, the thermally shrinkable adhesive tape is used as the protective tape 3 which is put on the front surface of the wafer 2 to protect the front surface of the wafer before the step of grinding the rear surface of the wafer 2, and the step of dividing the wafer 2 along the streets 21 formed in a lattice pattern is carried out in a state where the protective tape 3 is affixed to the front surface of the wafer 2 still after the rear surface grinding step. Therefore, a protective tape does not need to be put on the front surface of the wafer 2 again in order to prevent grinding chips produced by cutting from adhering to the front surfaces of the devices before the dividing step and consequently, the productivity is not reduced.

Further, since the thermally shrinkable adhesive tape is used as the protective tape 3 which is put on the front surface of the wafer 2, the protective tape pieces 30 produced by dividing the wafer 2 into individual chips 20 can be easily removed by heating the protective tape 3 after the above dividing step because they are curved and their adhesive force is reduced. Therefore, it does not affect the subsequent die bonding step, etc.

While the invention has been described above based on the illustrated embodiment, it is to be understood that the invention is not limited thereto but may be otherwise variously embodied within the scope of the invention. For example, in the above-described dividing step, the protective tape 3 and the wafer 2 are cut along the streets 21 with a single cutting blade 621. The protective tape 3 and the wafer 2 may be cut severally. That is, a cutting blade suitable for cutting a protective tape may be used to cut the protective tape 3 and another cutting blade suitable for cutting a wafer may be used to cut the wafer 2.

Further, in the above dividing step, the protective tape 3 and the wafer 2 are cut along the streets 21 with the cutting machine. In the dividing step, a laser beam may be applied along the streets 21 to divide the wafer into individual chips. Also in this case, as the protective tape 3 is affixed to the front surface 2a of the wafer 2, debris produced by applying the laser beam can be prevented from adhering to the front surfaces of the devices.

What is claimed is:

1. A wafer processing method for dividing a wafer having a plurality of streets formed in a lattice pattern on the front surface and having devices formed in a plurality of areas sectioned by the plurality of streets, along the streets, comprising:
a protective tape affixing step for putting a protective tape whose adhesive force is reduced by an external stimulus on the front surface of the wafer;
a rear surface grinding step for grinding the rear surface of the wafer having the protective tape to a predetermined thickness;
a wafer supporting step for supporting the rear surface of the wafer subjected to the rear surface grinding step by a wafer supporting means;
a dividing step for dividing the wafer supported by the wafer supporting means into individual chips along the streets together with the protective tape; and
an adhesive force reducing step for reducing the adhesive force of the protective tape by providing an external stimulus to the protective tape in a state where the wafer divided into individual chips by the dividing step is supported by the wafer supporting means.

2. The wafer processing method according to claim 1, wherein the protective tape is thermally shrinkable under heating, and heated in the adhesive force reducing step.

3. The wafer processing method according to claim 1, wherein the wafer supporting means is composed of an annular frame and a dicing tape which is so mounted as to cover the opening of the annular frame and has an adhesive layer on the surface, and the above wafer supporting step is to put the rear surface of the wafer on the surface of the dicing tape.
